(19) United States
(12) Patent Application Publication
(10) Pub. No.: US 2010/0300259 A1
(43) Pub. Date: Dec. 2, 2010

(54) SUBSTRATE SIDE MARKING AND IDENTIFICATION

(75) Inventor: BYUNGGON LEE, Andover, MA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/789,226

(22) Filed: May 27, 2010

Related U.S. Application Data
(60) Provisional application No. 61/182,209, filed on May 29, 2009.

(51) Int. Cl. B26D 3/08

(52) U.S. Cl. 83/879

(57) ABSTRACT

Embodiments of the present invention provide an accurate method for marking substrates for individual substrate identification and tracking during a solar cell fabrication process. In one embodiment, each crystalline silicon ingot is marked on at least two sides via a scribing technique. In one embodiment, each crystalline silicon ingot is marked on three sides via a scribing technique. The ingots are then sliced into individual substrates, which retain the clearly visible and robust markings on the sides of the substrate. In one embodiment, the markings are detected by images captured by a moderate resolution camera at desired locations through a solar cell production line. In one embodiment, the markings are manually readable at one or more desired points throughout the solar cell production process. In general, the combination of markings uniquely identifies each individual substrate, the ingot from which the substrate was sliced, and the location within the ingot from which the substrate was obtained.

### CROSS-REFERENCE TO RELATED APPLICATIONS

This application claims benefit of U.S. provisional patent application Ser. No. 61/182,209, filed May 29, 2009, which is herein incorporated by reference.

### BACKGROUND OF THE INVENTION

1. Field of the Invention

Embodiments of the present invention generally relate to a method and apparatus for individual substrate identification through marking of crystalline silicon ingots prior to substrate singulation. The invention may be particularly useful for identification and tracking of single substrates in the production of crystalline silicon solar cells as well as tracing an individual substrate to its source.

2. Description of the Related Art

Photovoltaic (PV) or solar cells are devices that convert sunlight into direct current electrical power. A typical solar cell includes a p-type silicon substrate with a thin layer of an n-type silicon material disposed on top of the p-type substrate, which defines a p-n junction. When exposed to sunlight, the p-n junction of the solar cell generates pairs of free electrons and holes. The electric field formed across a depletion region of the p-n junction separates the free electrons and holes, creating a voltage. A circuit from the n-side to the p-side of the solar cell allows the flow of electrons when the solar cell is connected to an electric load. Electrical power is the product of voltage times the current generated as the electrons and holes move through an external load and eventually recombine. Solar cells generate a specific amount of power and are tiled into modules sized to deliver a desired amount of system power. Solar modules are further joined into panels with specific frames and connectors.

The PV market has experienced annual growth rates exceeding 30% for the last ten years. Some articles suggest that solar cell power production worldwide may exceed 10 GWp in the near future. This high market growth rate in combination with the need to reduce solar electricity costs has resulted in a number of serious challenges for crystalline silicon solar cell fabrication.

One such challenge involves the need to identify and track individual crystalline silicon substrates before, during, and after the solar cell production process in order to identify and diagnose material or processing problems and maintain high device yields under high volume production. However, prior art methods are costly and are not robust enough to consistently withstand all phases of the fabrications process.

In the crystalline silicon solar cell process, thin substrates are sliced from an ingot (or block) of crystalline silicon material. One example of an ingot of crystalline silicon material has the dimensions of 156 mm×156 mm×500 mm. From this example, about 1800 individual substrates may be produced having a thickness of about 180 μm. As subsequently set forth, it is desirable to identify and track each individual substrate in the solar cell production process. Additionally, it is desirable to be able to identify both the ingot and the position within the ingot from which each individual substrate was produced to aid in quality assurance, such as isolating a batch of substrates produced from a problem area in a specific ingot. One method of tracking individual substrates involves marking the face of each individual substrate with a scribed bar code. Another suggested method involves marking an edge of each individual substrate with a barcode. Yet another suggested method involves marking one side of each ingot with a complex scribed bar coding system. However, these methods require expensive, high resolution cameras because of the high number and small size of pixels needed for self describing the unique identification marks and complex data management systems for tracking the unique identification marks. Further, the reliability of such systems is low. For instance because the face of the substrate must endure a number of thermal, etching, deposition, and other processes, complex bar codes on the face or one side of an individual substrate may be altered or damaged. Even slight damage to a complex bar code configuration may render the code unreadable be even the most advanced of imaging devices. Also, individually marking each individual substrate is time consuming, resulting in increased cycle time and cost in the solar cell production process. In addition, due to the complex nature and condensed spacing requirements of bar codes on crystalline silicon substrates, manual reading of such codes is not viable.

Therefore, there is a need for improved, simplified substrate marking techniques for identifying, tracing, and tracking individual substrates in the solar cell fabrication process.

### SUMMARY OF THE INVENTION

In one embodiment of the present invention, a method for substrate marking and identification comprises scribing a plurality of lines on a first side of an ingot, scribing a plurality of lines on a second side of the ingot, and slicing the ingot into a plurality of substrates, wherein each of the substrates has a first set of marks on a first edge corresponding to the plurality of lines scribed on the first side of the ingot, and wherein each of the substrates has a second set of marks on a second edge corresponding to the plurality of lines scribed on the second side of the ingot.

In another embodiment of the present invention, a method for substrate marking and identification comprises scribing a plurality of lines on a first side of an ingot, scribing a plurality of lines on a second side of the ingot, scribing a plurality of lines on a third side of the ingot, and slicing the ingot into a plurality of substrates, wherein each of the substrates has a first set of marks on a first edge corresponding to the plurality of lines scribed on the first side of the ingot, wherein each of the substrates has a second set of marks on a second edge corresponding to the plurality of lines scribed on the second side of the ingot, and wherein each of the substrates has a third set of marks on a third edge corresponding to the plurality of lines scribed on the third side of the ingot.

In yet another embodiment of the present invention, a method for substrate marking and identification comprises scribing a plurality of lines on a first side of an ingot, scribing a plurality of lines on a second side of the ingot, scribing a plurality of lines on a third side of the ingot, slicing the ingot into a plurality of substrates, wherein each of the substrates has a first set of marks on a first edge corresponding to the plurality of lines scribed on the first side of the ingot, wherein each of the substrates has a second set of marks on a second edge corresponding to the plurality of lines scribed on the second side of the ingot, and wherein each of the substrates has a third set of marks on a third edge corresponding to the plurality of lines scribed on the third side of the ingot, placing at least one of the substrates within an inspection module, and capturing at least one image of the at least one substrate via an inspection device.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, isometric view of an ingot having identification scribed lines marked on the sides thereof according to one embodiment of the present invention.

FIGS. 2A, 2B, and 2C are plan views of a first side, second side, and third side of the ingot shown in FIG. 1.

FIG. 3A is a plan view of a substrate taken from a region “A” of the ingot in FIG. 1.

FIG. 3B is a plan view of a substrate taken from a region “B” of the ingot in FIG. 1.

FIG. 4 is a schematic depiction of an inspection module used to analyze one or more substrates according to one embodiment of the present invention.

### DETAILED DESCRIPTION

Embodiments of the present invention provide an accurate method for marking substrates for individual substrate identification and tracking during a solar cell fabrication process. In one embodiment, each crystalline silicon ingot is marked on at least two sides via a scribing technique. In one embodiment, each crystalline silicon ingot is marked on three sides via a scribing technique. The ingots are then sliced into individual substrates, which retain the clearly visible and robust markings on the sides of the substrate. In one embodiment, the markings are detected by images captured by a moderate resolution camera at desired locations through a solar cell production line. In one embodiment, the markings are manually readable at one or more desired points throughout the solar cell production process. In general, the combination of markings uniquely identifies each individual substrate, the ingot from which the substrate was sliced, and the location within the ingot from which the substrate was obtained.

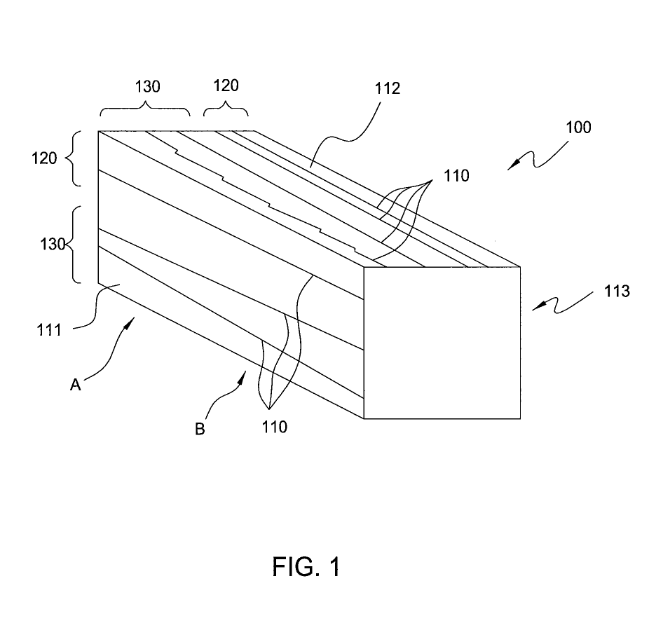

FIG. 1 is a schematic, isometric view of an ingot 100, such as a crystalline silicon ingot, having identification scribed lines 110 marked on the sides thereof according to one embodiment of the present invention. In one embodiment, the ingot 100 is marked with a number of scribed lines 110 on at least two sides thereof. In one embodiment, the ingot 100 is marked with a number of scribed lines 110 on three sides thereof. In one embodiment, the scribed lines 110 are produced via laser scribing. In other embodiments, the scribed lines 110 are produced via other scribing methods, such as water jet or diamond scribing. Regardless of the type of device used to produce the scribed lines 110, the scribed lines 110 should be such that they are manually visible and/or visible via moderate resolution imaging devices on substrates sliced from the ingot 100. Additionally, the scribing device should be capable of consistently producing precisely scribed lines 110 across the side of the ingot 100. In one embodiment, the scribed lines 110 are produced on each side of the ingot 100 in separate scribing operations, i.e., one operation for each side. In another embodiment, the scribed lines 110 are produced on more than one side at a time, e.g., two or three sides at a time. In one embodiment, each scribed line 110 has an identically shaped cross-section as depicted throughout the figures in the present application. In one embodiment, the scribed lines 110 may have differently shaped cross-sections to aid in recognition and identification.

As shown in FIG. 1, at least two sides of the ingot 100 have at least two sections of scribed lines 110 marked thereon. In one embodiment, each of the marked sides includes a position section 120 and a sequence section 130. The position section 120 may include a particular number and sequence of scribed lines 110 that indicate the side of the ingot 100 (or substrate sliced therefrom). The sequence section 130 may include a particular number and sequence of scribed lines 110 that identify the specific ingot 100 and the location of any particular region of the ingot 100.

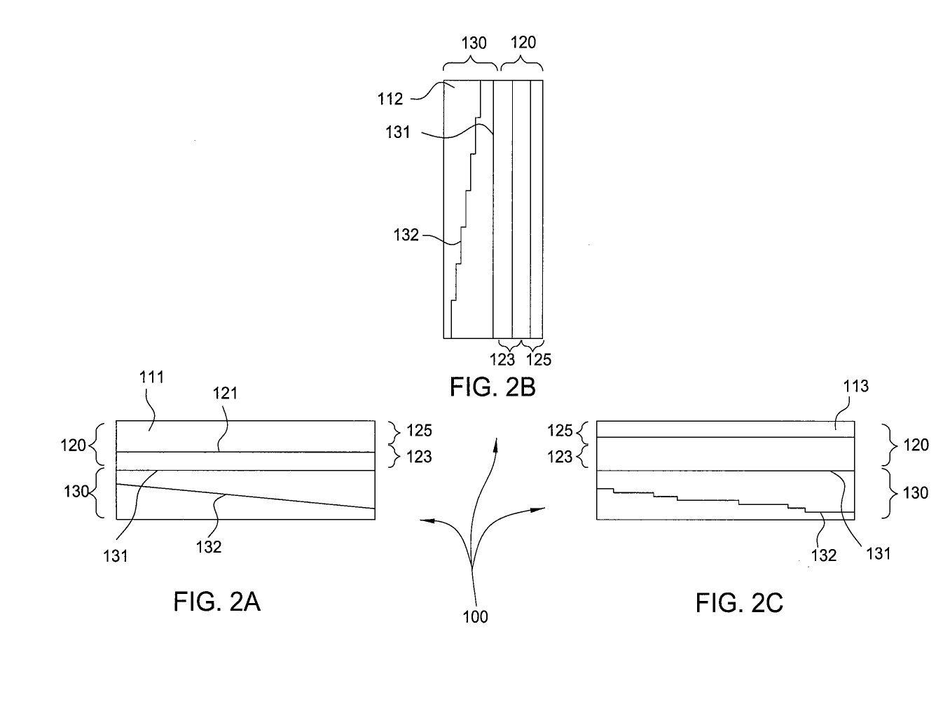

FIGS. 2A, 2B, and 2C are plan views of a first side 111, a second side 112, and a third side 113 of the ingot 100, respectively, as shown in FIG. 1 according to one embodiment of the present invention. In this example, the position section 120 includes one or more position lines 121 scribed in the position section 120 to identify the respective side of the ingot 100. In one embodiment, the existence of position lines 121 within particular portions of the position section 120 indicates the respective side. For instance, a position line 121 located in a lower portion 123 of the position section 120 without a position line 121 located in an upper portion 125 may identify the first side 111 of the ingot 100 as shown in FIG. 2A. Correspondingly, one position line 121 located in the lower portion 123 and one position line located in the upper portion 125 of the position section 120 may identify the second side 112 of the ingot 100 as shown in FIG. 2B. Further, a position line 121 located in the upper portion 125 of the position section 120 without a position line 121 located in the lower portion 123 of the position section 120 may identify the third side 113 of the ingot 100 as shown in FIG. 2C.

In another embodiment, the number of position lines 121 in the position section 120 identifies the respective side of the ingot 100. For instance, a single position line 121 within the position section 120 may identify the first side 111 of the ingot 100. Correspondingly, two position lines 121 located in the position section 120 may identify the second side 112 of the ingot, and three position lines located in the position section 120 may identify the third side 113 of the ingot 100.

In yet another embodiment, the location of a single position line 121 within the position section 120 identifies the respective side of the ingot 100. For instance, a single position line 121 within the lower portion 123 of the position section 120 may identify the first side 111 of the ingot 100. Correspondingly, a single position line 121 located within a middle portion of the position section may identify the second side 112, and a single position line 121 located within the upper portion 125 of the position section 120 may identify the third side 113 of the ingot 100.

Referring back to FIG. 1, the sequence section 130 of each side of the ingot 100 may include a plurality of scribed lines 110, which are collectively used to identify both the specific ingot 100 and the position within the ingot 100 from which a particular substrate originates. In the example shown in FIGS. 2A-2C, a single base line 131 and one or more sequence lines 132 may be scribed across the length of the ingot 100 within the sequence section 130. In one embodiment, the sequence line 132 may include one or more continuous lines scribed across the length of the ingot 100 at a specified angle with respect to the base line 131. In one embodiment, as shown in FIG. 2B, the sequence line 132 may include one or more stepped lines having a plurality of constant segments spanning the length of the ingot 100. In one embodiment, as shown in FIG. 2C, the sequence line 132 may include one or more stepped lines having a plurality of variable segments spanning the length of the ingot 100. In the embodiments shown in FIGS. 2B and 2C, each segment of the sequence lines 132 may represent a significant digit (e.g., 1234567689) for use in a digital identification scheme. For instance, in a nine digit identification scheme, the first through ninth segments may represent the first-ninth significant digits. In one embodiment, an additional digital (stepwise) scribe line (not shown) may be used as a checksum to validate the reading of the position and sequence lines/marks on a particular ingot/substrate.

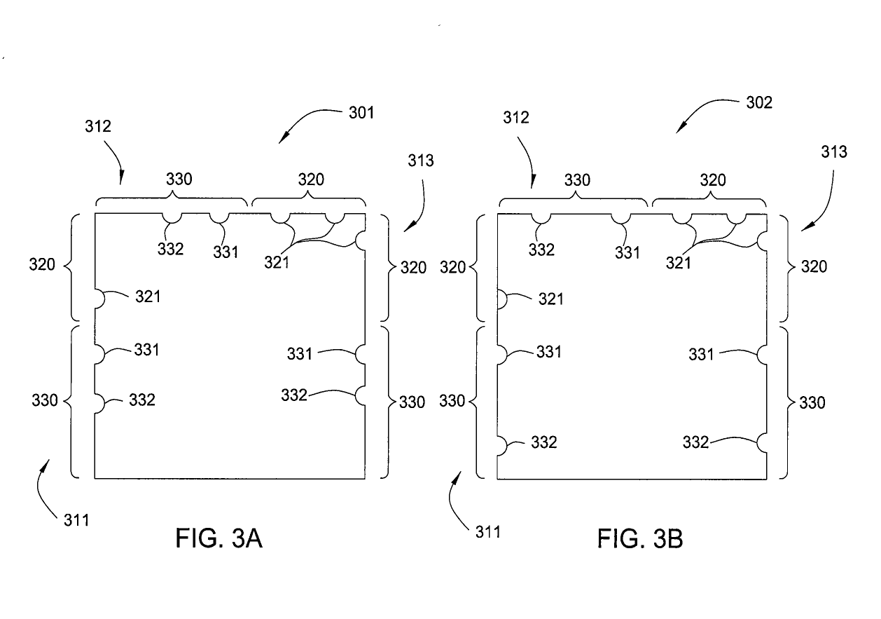

FIG. 3A is a plan view of a substrate 301 taken from a region “A” of the ingot 100. FIG. 3B is a plan view of a substrate 302 taken from a region “B” of the ingot 100 shown in FIG. 1. As shown in FIGS. 3A and 3B, each of the substrates 301, 302 has a plurality of scribe marks on three edges thereof corresponding to the scribe lines 110 on the ingot 100. In one embodiment, the identification of the substrate 301, 302 is determined by analysis of scribe marks, either manually or by an imaging source in conjunction with a system controller, as subsequently described. This information can then be used to both identify the origin of the substrate 301, 302 and to track the substrate 301, 302 through the solar cell fabrication process.

In one embodiment, the identification of the substrate side is determined by analysis of position marks 321 within position sections 320, which correspond to the position lines 121 as previously described with respect to FIGS. 2A-2C. In the examples shown in FIGS. 3A and 3B, analysis of the position marks 321 on the edges of the substrates 301, 302 identify a first edge 311, a second edge 312, and a third edge 313 of the substrates 301, 302, which correspond to the first side 111, the second side 112, and the third side 113 of the ingot 100.

In one embodiment, the scribe marks located within the sequence sections 330 of each substrate 301, 302 are analyzed. In the examples shown in FIGS. 3A and 3B, base marks 331 correspond to the base lines 131 and sequence marks 332 correspond to the sequence lines 132 of the ingot 100. In one embodiment, the relationship between the one or more sequence marks 332 and the respective base mark 331 is analyzed on each edge of the substrate 301, 302. This relationship (e.g., distance between the respective marks) is analyzed in conjunction with the previously analyzed position marks 321 and compared with the known positions of the respective scribe lines on the ingot 100. This analysis may be performed either manually or automated by a system controller. The results of the analysis reveal both the specific ingot 100 and the location within the ingot 100 from which the respective substrates 301, 302 originated as well as a unique identification of the respective substrates 301, 302. In one embodiment, the relative distance between respective marks and an ordering of these distances is used to provide unique identification of the respective substrates with respect to an ordering of these substrates within the ingot (e.g., the position of the substrate 301 with respect to the substrate 302 within the ingot 100). In another embodiment, the absolute distance between respective marks is used to uniquely determine a respective substrate (e.g., the substrate 301 is the fifteenth substrate sliced from the ingot 100).

In one embodiment, if a specific substrate is found to have quality problems (e.g., impurities) prior to, during, or after the solar cell fabrication process, further analysis can be conducted on other substrates originating from similar regions of the ingot from which the problem substrate originated. Thus, identification of the individual substrate according to the present invention not only facilitates quality assurance of the final product, but it also facilitates diagnosis and correction of any quality problems in the supply of crystalline silicon ingots as well.

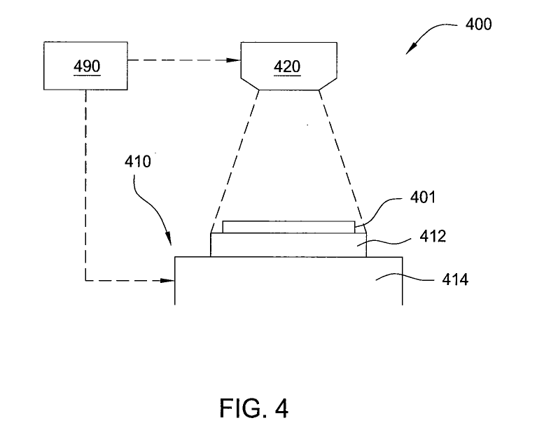

FIG. 4 is a schematic depiction of an inspection module 400 which may be used to analyze one or more substrates 401, such as the substrates 301, 302, according to the present invention. In one embodiment, the inspection module 400 comprises a support mechanism 410 for supporting the one or more substrates 401 and an inspection device 420 for inspecting the one or more substrates 401. In one embodiment, the one or more substrates 401 are positioned in a substrate carrier 412, which may be configured to hold a single substrate or a plurality of substrates. The support mechanism 410 may include a conveying mechanism 414 having rollers, belts, and other conventional conveyor components needed to transport the one or more substrates 401 through the inspection module 400. In one embodiment, the movement of substrates 401 on the conveying mechanism 414 is controlled via a system controller 490.

In one embodiment, the system controller 490 is not only in communication with the inspection module 400, but it is also in communication with a plurality of other processing modules used in the solar cell fabrication process, such as in a solar cell production line. In one embodiment, the system controller 490 facilitates the control and automation of a plurality of modules within a solar cell production line, including the inspection module 400. The system controller 490 may include a central processing unit (CPU) (not shown), memory (not shown), and support circuits (or I/O) (not shown). The CPU may be one of any form of computer processors that are used in industrial settings for controlling various processes and hardware (e.g., conveyors, optical inspection assemblies, motors, fluid delivery hardware, etc.) and monitor the system and processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 490 determines which tasks are performable on a substrate. Preferably, the program is software readable by the system controller 490, which includes code to generate and store at least substrate positional information, substrate identification information, substrate origin information, the sequence of movement of the various controlled components, substrate optical inspection system information, and any combination thereof.

In one embodiment, the inspection device 420 comprises one or more moderate resolution cameras configured to capture images of the one or more substrates 401. In one embodiment, the inspection device 420 comprises one or more cameras having moderate resolution capabilities. In one embodiment, the moderate resolution capabilities include a pixel size from about 5 μm to about 20 μm. In one embodiment, the images are manually inspected, and identification and any corrective actions needed are performed manually. In one embodiment, the inspection device 420 is in communication with the system controller 490. In such an embodiment, the inspection device 420 sends captured images to the system controller 490 for analysis, identification of each particular substrate 401, and storage for use in tracking each particular substrate through the solar cell production process. Thus, information regarding the identification of each individual substrate 401 may not only be used for tracing the origin of the substrate 401, but it may also be used during the fabrication process for tracking each individual substrate 401 through each step of the fabrication process. In one embodiment, a plurality of additional information is retrieved, analyzed, and stored regarding each individual substrate 401 at each step of the solar cell fabrication process. This information may not only be used for quality assurance of each solar cell fabricated, but it may also be used to diagnose and tune various processes within the solar cell production line in real time.

Therefore, an accurate system and method for marking and identifying crystalline silicon substrates for origin traceability, production tracking, and quality assurance are provided. The present invention uses an accurate scheme of marking multiple sides of an ingot prior to substrate singulation. The result is a substrate having a consistent marking scheme on multiple edges thereof that are clearly visible for manual and/or automated identification. Additionally, the utilization of multiple sides of the substrate significantly improves the reliability of the identification system as well.

While the foregoing is directed to embodiments of the present invention, other and further embodiments of the invention may be devised without departing from the basic scope thereof, and the scope thereof is determined by the claims that follow.

1. A method for substrate marking and identification, comprising:
scribing a plurality of lines on a first side of an ingot;
scribing a plurality of lines on a second side of the ingot; and
slicing the ingot into a plurality of substrates, wherein each of the substrates has a first set of marks on a first edge corresponding to the plurality of lines scribed on the first side of the ingot, and wherein each of the substrates has a second set of marks on a second edge corresponding to the plurality of lines scribed on the second side of the ingot.

2. The method of claim 1, wherein at least one of the plurality of lines on the first side of the ingot is scribed in a first position section and at least two of the plurality of lines on the first side of the ingot is scribed in a first sequence section.

3. The method of claim 2, wherein at least one of the plurality of lines on the second side of the ingot is scribed in a second position section and at least two of the plurality of lines on the second side of the ingot is scribed in a second sequence section.

4. The method of claim 3, wherein the lines scribed in the first and second position sections identify the side of the ingot, and wherein the lines scribed in the first and second sequence sections identify the location along the ingot.

5. The method of claim 1, wherein the first set of marks include at least one mark in a position section of the first edge of each substrate, and wherein the first set of marks include marks in a sequence section of the first edge of each substrate.

6. The method of claim 5, wherein the second set of marks include marks in a position section of the second edge of each substrate, and wherein the second set of marks include marks in a sequence section of the second edge of each substrate.

7. The method of claim 6, wherein the marks in the position section of the first and second edges of each substrate identify the side of the ingot from which the substrate was sliced, and wherein the marks in the sequence section of the first and second edges of each substrate identify the location along the length of the ingot from which the substrate was sliced.

8. The method of claim 1, further comprising:
placing at least one of the substrates within an inspection module;
capturing at least one image of the at least one substrate via an inspection device;
analyzing the at least one image of the at least one substrate via a system controller to determine the positions of the first and second sets of marks; and
tracing the at least one substrate to the location within the ingot from which it was sliced using the determined positions.

9. The method of claim 1, further comprising:
placing at least one of the substrates within an inspection module;
capturing at least one image of the at least one substrate via an inspection device;
analyzing the at least one image of the at least one substrate via a system controller to determine the positions of the first and second sets of marks; and
tracking the at least one substrate through a solar cell fabrication process using the determined positions.

10. A method for substrate marking and identification, comprising:
scribing a plurality of lines on a first side of an ingot;
scribing a plurality of lines on a second side of the ingot;
scribing a plurality of lines on a third side of the ingot; and
slicing the ingot into a plurality of substrates, wherein each of the substrates has a first set of marks on a first edge corresponding to the plurality of lines scribed on the first side of the ingot, wherein each of the substrates has a second set of marks on a second edge corresponding to the plurality of lines scribed on the second side of the ingot, and wherein each of the substrates has a third set of marks on a third edge corresponding to the plurality of lines scribed on the third side of the ingot.

11. The method of claim 10, wherein at least one of the plurality of lines on the first side of the ingot is scribed in a first position section and at least two of the plurality of lines on the first side of the ingot is scribed in a first sequence section, wherein at least one of the plurality of lines on the second side of the ingot is scribed in a second position section and at least two of the plurality of lines on the second side of the ingot is scribed in a second sequence section, and wherein at least one of the plurality of lines on the third side of the ingot is scribed in a third position section and at least two of the plurality of lines on the third side of the ingot is scribed in a third sequence section.

12. The method of claim 11, wherein the lines scribed in the first, second, and third position sections identify the side of the ingot.

13. The method of claim 11, wherein the lines scribed in the first, second, and third sequence sections identify the location along the ingot.

14. The method of claim 10, wherein the first set of marks include at least one mark in a position section of the first edge of each substrate, and wherein the first set of marks include marks in a sequence section of the first edge of each substrate.

15. The method of claim 14, wherein the second set of marks include marks in a position section of the second edge of each substrate, and wherein the second set of marks include marks in a sequence section of the second edge of each substrate.

16. The method of claim 15, wherein the third set of marks include marks in a position section of the third edge of each substrate, and wherein the second set of marks include marks in a sequence section of the second edge of each substrate.

17. The method of claim 16, wherein the marks in the position section of the first, second, and third edges of each substrate identify the side of the ingot from which the substrate was sliced, and wherein the marks in the sequence section of the first, second, and third edges of each substrate identify the location along the length of the ingot from which the substrate was sliced.

18. A method for substrate marking and identification, comprising:
scribing a plurality of lines on a first side of an ingot;
scribing a plurality of lines on a second side of the ingot;
scribing a plurality of lines on a third side of the ingot;
slicing the ingot into a plurality of substrates, wherein each of the substrates has a first set of marks on a first edge corresponding to the plurality of lines scribed on the first side of the ingot, wherein each of the substrates has a second set of marks on a second edge corresponding to the plurality of lines scribed on the second side of the ingot, and wherein each of the substrates has a third set of marks on a third edge corresponding to the plurality of lines scribed on the third side of the ingot;
placing at least one of the substrates within an inspection module; and
capturing at least one image of the at least one substrate via an inspection device.

19. The method of claim 18, further comprising:
analyzing the at least one image of the at least one substrate via a system controller to determine the positions of the first, second, and third sets of marks; and
tracing the at least one substrate to the location within the ingot from which it was sliced using the determined positions.

20. The method of claim 18, further comprising:
analyzing the at least one image of the at least one substrate via a system controller to determine the positions of the first, second and third sets of marks; and
tracking the at least one substrate through a solar cell fabrication process using the determined positions.
